(19) United States
(12) Patent Application Publication
(10) Pub. No.: US 2004/0241954 A1
(43) Pub. Date: Dec. 2, 2004

(54) Method for forming a crown capacitor

(75) Inventors: Yi-Nan Chen, Taipei (TW); Tie-Jiang Wu, Ilan (TW); Chung-Yuan Lee, Taoyuan (TW)

Correspondence Address: QUINTERO LAW OFFICE, 1617 BROADWAY, 3RD FLOOR, SANTA MONICA, CA, 90404, US

(73) Assignee: Nanya Technology Corporation

(21) Appl. No.: 10/653,730

(22) Filed: Sep. 2, 2003

(30) Foreign Application Priority Data
May 30, 2003 (TW) 92114688

(51) Int. Cl. H01L 21/8242; H01L 21/20

(52) U.S. Cl. 438/386; 438/243

(57) ABSTRACT

The invention provides a method for forming a crown capacitor. A semiconductor substrate having a pad stacked layer on the surface and a trench formed therein is provided. Next, a buried plate in the substrate around the bottom part of the trench is formed, followed by the formation of a lower plate in the trench without covering the sidewall of the trench. A crown-shaped capacitor dielectric layer is thus formed along the sidewall of the trench and the lower plate. This crown capacitor, having a capacitor dielectric layer with greater surface area, provides greater capacitance.

### BACKGROUND OF THE INVENTION

1. Field of the Invention

The invention relates to a method for forming crown capacitors, and in particular, relates to a method for fabricating a metal-insulator-metal (MIM) capacitor.

2. Description of the Related Art

Capacitors are used for accessing signals in DRAMs. The more electric charges are stored, the less data-reading is impacted by noise. Methods of increasing electric charge storage include increasing dielectric constant (k) of the capacitor dielectric layer, or the surface area of a capacitor. In advanced DRAM technology, 3D-structured crown-type or small size trench capacitors, and high k (dielectric constant) materials are widely applied. Most capacitors are comprised of polysilicon-insulator-polysilicon, which is the so-called metal-insulator-silicon (MiS) structure. Alternatively, a metal-insulator-metal (MiM) is also applicable.

Crown-type capacitors having rugged electrodes contain a greater capacitance area and provides effective capacitance. Therefore, they are well suited for highly-integrated elements, especially for memory devices greater than 64 MB.

The current process for forming crown capacitors is, however, complicated and the capacitance no longer satisfies requirements, thus production efficiency is adversely affected. For some modified processes, production steps are simplified, but requirements for process control is relatively more strict and disadvantageous to production.

### SUMMARY OF THE INVENTION

Accordingly, an object of the invention is to provide a method for forming crown capacitors, which provides a simplified procedure for capacitors with greater capacitance areas.

In order to obtain the object, the invention provides a method for forming a crown capacitor, comprising the steps of: providing a semiconductor substrate having a pad stacked layer on the surface and a trench formed therein; forming a doped sidewall dielectric layer covering a sidewall of the trench; forming a lower plate by filling conductive material in the trench to a predetermined depth; partially removing the sidewall dielectric layer to a level below the lower plate; driving the ions doped in the sidewall dielectric layer into the semiconductor substrate to form a buried plate; removing the sidewall dielectric layer; forming a crown-shaped capacitor dielectric layer covering the pad stacked layer, the sidewall and the bottom of the trench and the lower plate; forming a upper plate by filling the trench with conductive material; and removing the capacitor dielectric layer covering the pad stacked layer, and the capacitor dielectric layer not covered by the upper plate, and the surface of the capacitor dielectric layer is below that of the upper plate.

The method further comprises: forming a collar dielectric layer on the sidewall of the trench to cover the capacitor dielectric layer and a portion of the upper plate; forming a first conductive layer by filling conductive material to the area surrounded by the collar dielectric layer; and forming a second conductive layer by filling conductive material on the collar dielectric layer and the first conductive layer.

A detailed description is given in the following embodiments with reference to the accompanying drawings.

### BRIEF DESCRIPTION OF THE DRAWINGS

The present invention can be more fully understood by reading the subsequent detailed description and examples with references made to the accompanying drawings, wherein:

FIGS. 1A-1J are cross sections illustrating the process according to the embodiment of the invention.

### DETAILED DESCRIPTION OF THE INVENTION

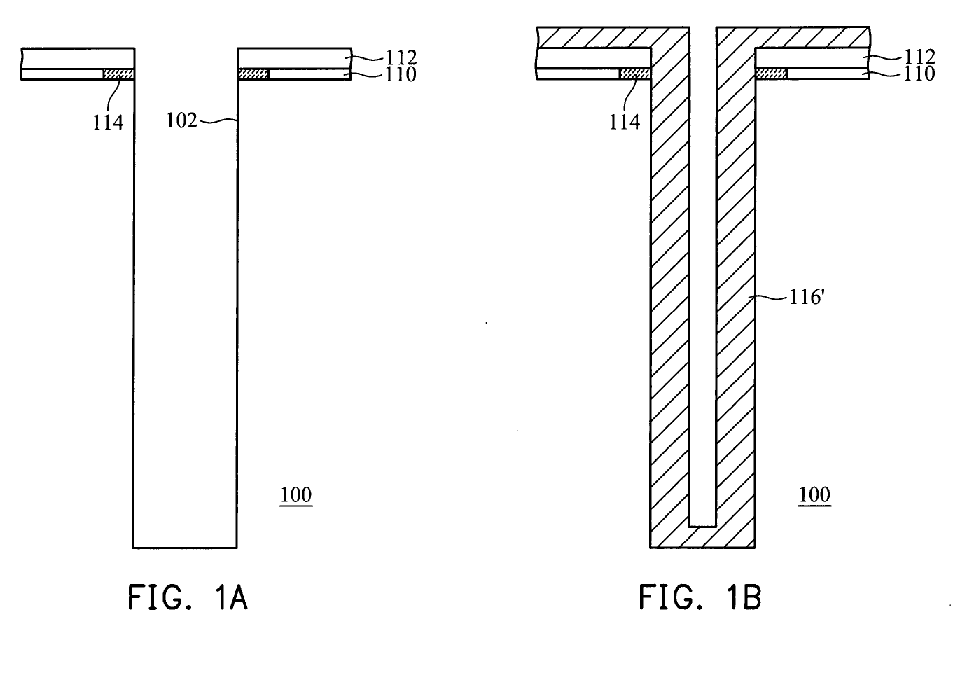

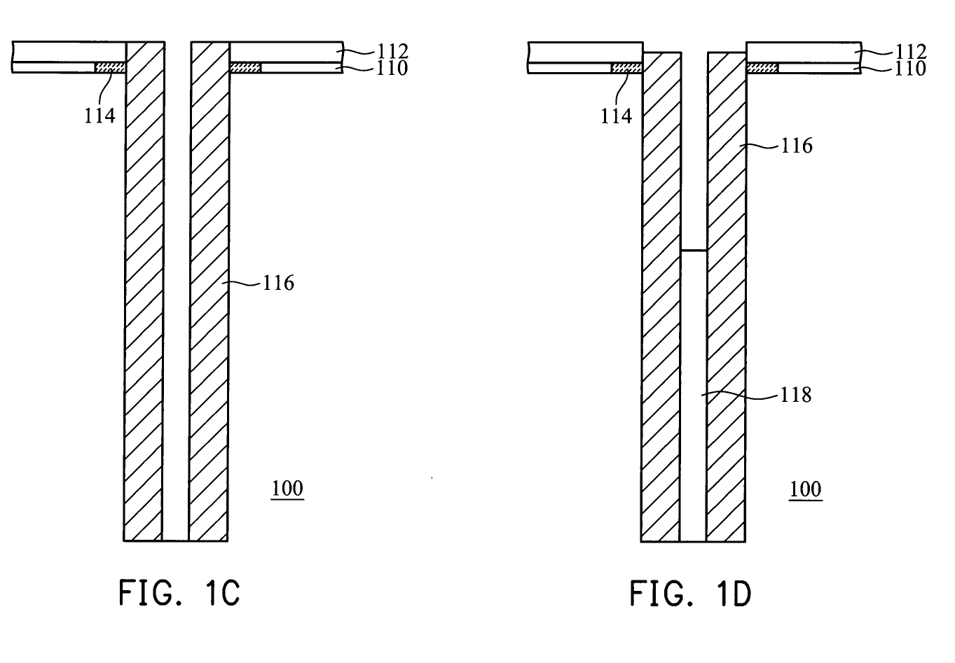

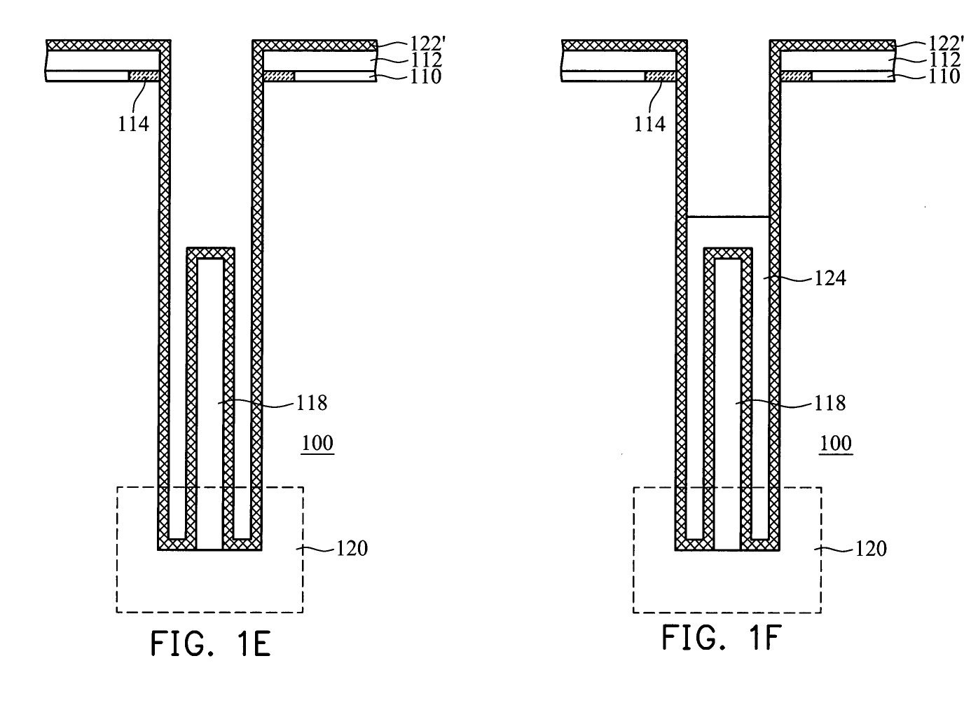

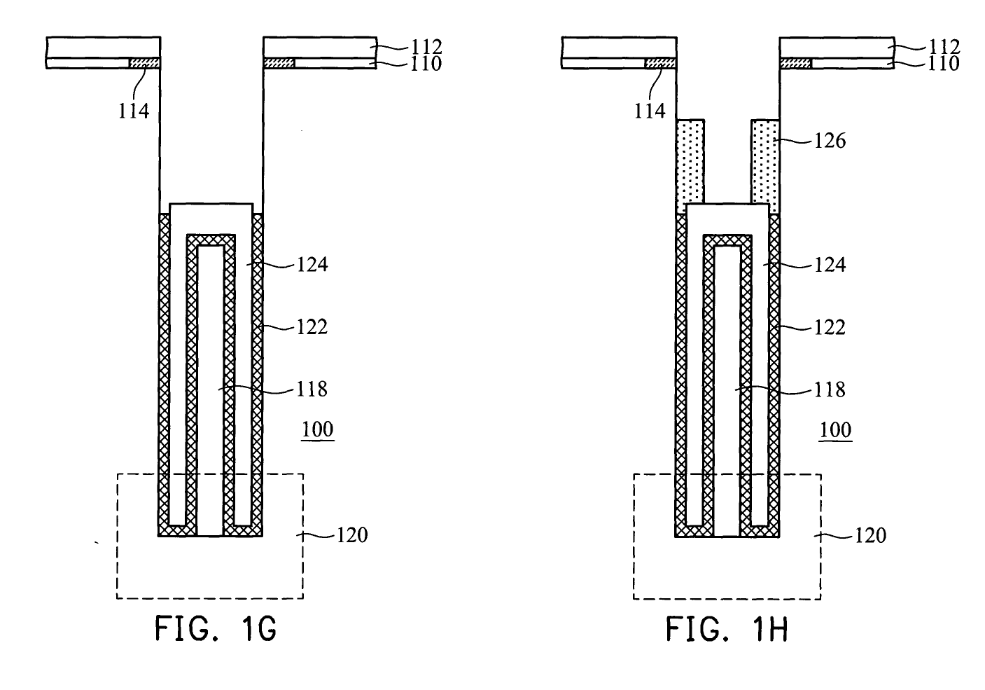

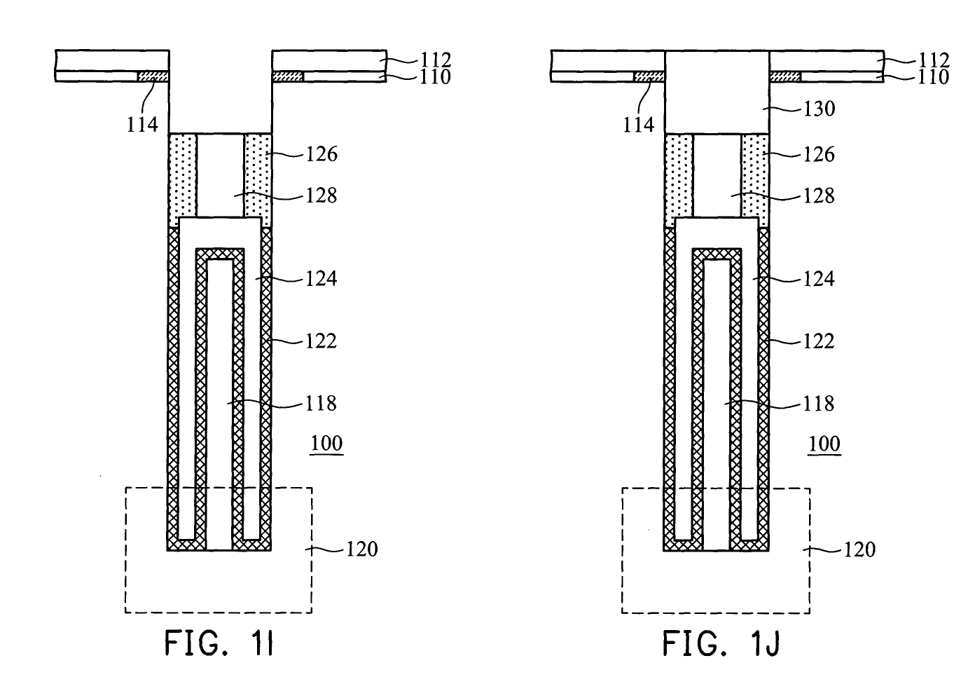

FIGS. 1A-1J illustrate cross sections of the method for forming a crown capacitor according to the invention.

As shown in FIG. 1A, a semiconductor substrate 100 having a pad stacked layer on the surface is provided. The pad stacked layer comprises an oxide layer 110 and a nitride layer 112. Preferable thickness of the oxide layer is 20-100Å and preferable thickness of the nitride is 200-500 angstroms. The pad stacked layer is formed preferably by chemical vapor deposition (CVD).

Next, an opening is formed on the pad stacked layer to expose a partial surface of the semiconductor substrate. This is carried out by coating photoresist material, followed by photolithography to form a photoresist pattern on the pad stacked layer. Reactive ion etching or plasma etching is then used to form the opening on the pad stacked layer. Then, plasma etching is performed to etch the exposed substrate to form a trench 102.

In order to prevent partial removal of the oxide layer 110 next to the trench 102 during the subsequent wet etching, a pad nitride layer 114 is formed at the end of the oxide layer 112 next to the trench 102. After the formation of the trench 102, pre-cleaning is performed with hydrogen fluoride (HF) to remove a portion of the oxide layer 110. Then, chemical vapor deposition is performed to form the pad nitride layer 114 at the end of the oxide layer 110 next to the trench. Next, HF/EG (ethylene glycol) or hot phosphoric acid is used to remove excess nitride.

Next, as shown in FIG. 1B, a N+ doped dielectric layer 116′, such as arsenic doped silicon glass (ASG) is formed conformally to cover the pad stacked layer and the sidewall and the bottom of the trench. Anisotropic etching, such as dry etching, is used to partially remove the dielectric layer. Thus, the dielectric layer remaining on the sidewall of the trench is the doped sidewall dielectric layer 116, as shown in FIG. 1C. The arsenic doped silicon glass (ASG) is preferably formed by low pressure chemical vapor deposition (LPCVD). Preferable thickness of the doped layer is 300±10 angstroms, for a 0.11 μm process.

Next, as shown in FIG. 1D, conductive material is filled in the area surrounded by the sidewall dielectric layer 116, followed by etching back to lower its height, thus forming a lower plate 118. The conductive material is preferably N+ doped polysilicon, and its height defines that of the capacitor dielectric layer formed thereafter. The height of the conductive material is not limited and can be modified accordingly. A preferable method for filling the conductive material is low pressure chemical vapor deposition (LPCVD).

Then, part of the doped sidewall dielectric layer is etched away so that its surface is lowered, by wet etching, to a level below that of the lower plate. Annealing is then performed to drive ions in the doped sidewall dielectric layer into the substrate to form an N+ doped region as the buried plate 120, as shown in FIG. 1E. The amount of the doped sidewall dielectric layer removed by wet etching defines the size of the formed buried plate. Preferably wet etching is performed with hydrogen fluoride. HF is then used to remove the sidewall dielectric layer 116 completely, thus exposing the sidewall of the trench.

A dielectric layer 122′ is then conformally formed to cover the pad stacked layer, the sidewall and the bottom of the trench, as shown in FIG. 1E. Due to the shape of the lower plate formed in the trench, the dielectric layer formed is in the shape of a crown, and has a rugged surface. Preferable thickness of the dielectric layer is 40±4Å. The dielectric layer is preferably formed by chemical vapor deposition, and has a nitride/oxide (NO) or an oxide/nitride/oxide (ONO) structure.

An upper plate 124 is then formed by filling conductive material in the space between the crown-shaped dielectric layer 122′, by low pressure chemical vapor deposition (LPCVD), followed by CMP/etching back to a level below that of the trench surface, as shown in FIG. 1F. The conductive material is preferably P+ doped polysilicon. The upper plate 124 of the capacitor is isolated from the lower plate 118 by the capacitor dielectric layer 122.

The capacitor dielectric layer 122 is then formed by removing the dielectric layer 122′ not covered by the upper plate 124 and on the pad stacked layer, as shown in FIG. 1G. The height of the capacitor dielectric layer 122 is set to be lower than that of the first conductive layer 124.

Next, a conductive wire is formed on the crown capacitor for connection with the transistor formed thereafter. Low pressure CVD or plasma enhanced CVD or high density CVD is used to conformally deposit dielectric material, such as tetraethylorthosilane, to cover the pad stacked layer and the sidewall and the bottom of the trench. Anisotropic etching is then used to partially remove the dielectric material to form the collar dielectric layer 126 surrounding the sidewall of the trench and covering a portion of the upper plate and the capacitor dielectric layer, as shown in FIG. 1H. Preferable thickness of the collar dielectric layer is 300±30 angstroms.

Next, a conductive material, such as P+ doped polysilicon is filled in the area surrounded by the collar dielectric layer 126 by low pressure CVD. A first conductive layer 128 is thus formed. Etching back or chemical mechanical polishing (CMP) is then carried out to make the height of the first conductive layer equal to that of the collar dielectric layer 126, as shown in FIG. 1I.

Finally, the same deposition method is performed to fill conductive material, such as P+ doped polysilicon in the trench to form a second conductive layer 130, as shown in FIG. 1J. The collar dielectric layer 126, the first conductive layer 128 and the second conductive layer 130, thus form the conductive wire for electrical connection of the crown capacitor and the transistor formed thereafter.

According to the method provided in the invention, the capacitance area of the crown capacitor increases because of the rugged surface area of the capacitor dielectric layer. Therefore, capacitance is increased and it is advantageous to enhance the overall performance of semiconductor elements.

While the invention has been described by way of example and in terms of the preferred embodiments, it is to be understood that the invention is not limited to the disclosed embodiments. To the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A method for forming a crown capacitor, comprising:
providing a semiconductor substrate having a pad stacked layer on the surface and a trench formed therein;
forming a doped sidewall dielectric layer covering a sidewall of the trench;
forming a lower plate by filling conductive material in the trench to a predetermined depth;
removing the sidewall dielectric layer partially so that the surface of the sidewall dielectric layer is lower than that of the lower plate;
driving the ions doped in the sidewall dielectric layer into the semiconductor substrate to form a buried plate;
removing the sidewall dielectric layer to expose the sidewall of the trench;
forming a crown-shaped capacitor dielectric layer conformally covering the pad stacked layer, the sidewall, and the bottom of the trench and the lower plate;
forming a upper plate by filling the space between the crown-shaped capacitor dielectric layer with conductive material; and
removing the capacitor dielectric layer covering the pad stacked layer, and the capacitor dielectric layer not covered by the upper plate, and the surface of the capacitor dielectric layer is below that of the upper plate.

2. The method according to claim 1, further comprising:
forming a collar dielectric layer on the sidewall of the trench to cover the capacitor dielectric layer and a portion of the upper plate;
forming a first conductive layer in the trench by filling conductive material in the area surrounded by the collar dielectric layer; and
forming a second conductive layer in the trench by filling conductive material on the collar dielectric layer and the first conductive layer.

3. The method according to claim 1, wherein the pad stacked layer comprises a nitride layer and an oxide layer and the ends of the oxide layer next to the trench further comprises a pad nitride layer.

4. The method according to claim 1, wherein the sidewall dielectric layer is arsenic doped silicon glass (ASG).

5. The method according to claim 1, wherein the conductive material is As doped polysilicon.

6. The method according to claim 1, wherein the capacitor dielectric layer is oxide-nitride-oxide (ONO) or nitride-oxide (NO).

7. The method according to claim 1, wherein the collar dielectric layer is tetraethylorthosilane(TEOS).

8. The method according to claim 1, wherein the thickness of the doped sidewall dielectric layer is 300Å±30.

9. The method according to claim 1, wherein the thickness of the collar dielectric layer is 300Å±30.

10. A method for forming a crown capacitor, comprising:
providing a semiconductor substrate having a pad stacked layer on the surface and a trench formed therein;
forming a doped sidewall dielectric layer covering a sidewall of the trench;
forming a lower plate by filling conductive material in the trench to a predetermined height;
removing a portion of the sidewall dielectric layer lowering it to a level below the lower plate;
driving the ions doped in the sidewall dielectric layer to the semiconductor substrate to form a buried plate;
removing the sidewall dielectric layer;
forming a crown-shaped capacitor dielectric layer by filling dielectric material to cover the pad stacked layer, the sidewall, and the bottom of the trench and the lower plate;
forming an upper plate by filling the trench with conductive material;
removing the capacitor dielectric layer covering the pad stacked layer, and the capacitor dielectric layer not covered by the upper plate so that the surface of the capacitor dielectric layer is below that of the upper plate;
forming a collar dielectric layer in the trench to cover the capacitor dielectric layer and a portion of the upper plate;
forming a first conductive layer by filling conductive material to the area surrounded by the collar dielectric layer; and
forming a second conductive layer by filling conductive material on the collar dielectric layer and the first conductive layer.

11. The method according to claim 10, wherein the pad stacked layer comprises a nitride layer and an oxide layer and the end of the oxide layer next to the trench comprises a pad nitride layer.

12. The method according to claim 10, wherein the sidewall dielectric layer is arsenic doped silicon glass (ASG).

13. The method according to claim 10, wherein the conductive material is As doped polysilicon.

14. The method according to claim 10, wherein the capacitor dielectric layer is oxide-nitride-oxide (ONO) or nitride-oxide (NO).

15. The method according to claim 10, wherein the collar dielectric layer is tetraethylorthosilane(TEOS).

16. The method according to claim 10, wherein the thickness of the doped sidewall dielectric layer is 300±30 angstroms.

17. The method according to claim 10, wherein the thickness of the collar dielectric layer is 300±30 angstroms.
